(19) United States
(12) Patent Application Publication
(10) Pub. No.: US 2026/0032954 A1
(43) Pub. Date: Jan. 29, 2026

(54) STACKABLE AND SELF-ALIGNED TFT STRUCTURES

(71) Applicant: ZINITE CORPORATION, Edmonton (CA)

(72) Inventor: Douglas BARLAGE, Edmonton (CA)

(21) Appl. No.: 19/274,380

(22) Filed: Jul. 18, 2025

Related U.S. Application Data
(60) Provisional application No. 63/674,725, filed on Jul. 23, 2024.
(60) Provisional application No. 63/711,776, filed on Oct. 25, 2024.
(60) Provisional application No. 63/713,504, filed on Oct. 29, 2024.
(60) Provisional application No. 63/814,628, filed on May 30, 2025.

(51) Int. Cl. H10D 30/67; H10D 30/01; H10D 86/01; H10D 86/40

(52) U.S. Cl. CPC H10D 30/6713; H10D 30/0314; H10D 30/6731; H10D 30/6757; H10D 86/0221; H10D 86/441

(57) ABSTRACT

An example thin-film transistor includes a source, including a body of source material, and a drain spaced apart from the source, the drain including a body of drain material. The thin-film transistor further includes a structure of layers between the source and the drain. The structure of layers includes a layer of metal-oxide semiconductor channel material, a layer of dielectric material, and a layer of gate material. The source, the drain, and the structure of layers terminate at a common planar surface. During manufacture, planarization, such as etching or chemical mechanical polishing, is used to form the common planar surface.

### CROSS-REFERENCE TO RELATED APPLICATIONS

This application claims priority to and the benefit of U.S. provisional patent app. Ser. No. 63/674,725, filed Jul. 23, 2024; U.S. provisional patent app. Ser. No. 63/711,776, filed Oct. 25, 2024; U.S. provisional patent app. Ser. No. 63/713,504, filed Oct. 29, 2024; and U.S. provisional patent app. Ser. No. 63/814,628, filed May 30, 2025. The entirety of each of these applications is incorporated herein by reference.

### FIELD

The present disclosure relates to thin-film transistors and related methods.

### BACKGROUND

In integrated circuits, such as processor and memory chips, transistor density limits the performance and capabilities of such circuits. The limits of Moore's Law, in two dimensions, are expected to be reached in the near future. While three-dimensional chip structures have been proposed, only chiplets and similar designs have been widely adopted.

### SUMMARY

According to an aspect of the present disclosure, a method of making a thin-film transistor includes forming a structure of layers between and over a source and a drain. The structure of layers includes a layer of metal-oxide semiconductor channel material, a layer of dielectric material, and a layer of gate material. The method further includes planarizing the structure to remove portions of the layers that overlie the source and the drain.

The planarizing may include planarizing the structure to a source carrier reservoir of the source that overlies a body of source material of the source.

The planarizing may include etching, chemical mechanical polishing, or both.

The method may further include forming an adhesion layer of tin oxide on a substrate and forming bodies of source and drain material on the adhesion layer. The adhesion layer may promote adhesion of the bodies of source and drain material to the substrate. The substrate may be an interlayer dielectric.

The method may further include forming a source-channel interface at a body of source material of the source. The source-channel interface contacts the metal-oxide semiconductor channel material and is operable to deplete a region of the metal-oxide semiconductor channel material when the thin-film transistor is off. The method may further include doping the source-channel interface with nitrogen, chlorine, fluorine, or a combination of two or more of such.

The method may further include forming a drain-channel interface at a body of drain material of the drain. The drain-channel interface may be formed in the same manner as the source-channel interface.

The method may further include forming a layer of intermediate contact material over the source and drain to provide ohmic contact to an electrode. The intermediate contact material may define a limit of the planarizing.

The method may further include forming a substrate over a planar surface formed by the planarizing and forming another thin-film transistor over the substrate, including forming and planarizing another structure of layers. The substrate may be an interlayer dielectric.

According to another aspect of the present disclosure, a thin-film transistor includes a source, including a body of source material, and a drain spaced apart from the source, the drain including a body of drain material. The thin-film transistor further includes a structure of layers between the source and the drain. The structure of layers includes a layer of metal-oxide semiconductor channel material, a layer of dielectric material, and a layer of gate material. The source, the drain, and the structure of layers terminate at a common planar surface.

The source may further include a source carrier reservoir that overlies the body of source material.

The thin-film transistor may further include a substrate and an adhesion layer of tin oxide formed on the substrate. The bodies of source and drain material are formed on the adhesion layer. The adhesion layer promotes adhesion of the bodies of source and drain material to the substrate. The substrate may be an interlayer dielectric.

The thin-film transistor may further include an intermediate contact layer at the source to provide ohmic contact to an electrode. The intermediate contact layer may be formed of silicon doped tin.

According to another aspect of the present disclosure, a stacked arrangement of thin-film transistors includes a stack formed of stack units, each stack unit including a plurality of thin-film transistors. Each thin-film transistor of the plurality of thin-film transistors includes a source, a drain spaced apart from the source, and a structure of layers between the source and the drain. The structure of layers includes a layer of metal-oxide semiconductor channel material, a layer of dielectric material, and a layer of gate material. The source, the drain, and the structure of layers terminate at a common planar surface.

Each stack unit may further include interlayer dielectric on which the source and drain of respective thin-film transistors are formed.

Each stack unit may further include interconnect wiring to electrically connect selected ones of the thin-film transistors within a respective stack unit, between different stack units, or both within the respective stack unit and between the different stack units.

These and other aspects of the present disclosure will be discussed in further detail below.

### BRIEF DESCRIPTION OF THE FIGURES

FIG. 1 is a cross-sectional view of an example thin-film transistor.

FIG. 2 is a cross-sectional view of an example thin-film transistor with a source-channel interface.

FIG. 3 is a cross-sectional view of the thin-film transistor of FIG. 2 with example electrode connections.

FIG. 4 is a cross-sectional view of the thin-film transistor of FIG. 2 as a unit stack with interlayer dielectric.

FIGS. 5A-5F are cross-sectional views of an example method of manufacturing a thin-film transistor.

FIG. 6 is a cross-sectional view of an example source/drain treatment process useable with the method of FIGS. 5A-5F.

FIG. 7 is a cross-sectional view of an example partially manufactured thin-film transistor about section line A-A of FIG. 5F.

FIG. 8 is a cross-sectional view about section line B-B of FIGS. 1 and 2.

FIG. 9 is a cross-sectional view about section line C-C of FIGS. 1 and 2.

FIG. 10 is a cross-sectional view of an example thin-film transistor with source/drain intermediate contact layers.

FIG. 11 is a cross-sectional view of a process of forming an example layer of intermediate contact material useable with the method of FIGS. 5A-5F.

FIG. 12 is a cross-sectional view of an example stack of thin-film transistors.

### DETAILED DESCRIPTION

The present disclosure relates to stackable and self-aligned structures of thin-film transistors (TFTs), which may help increase the density and capabilities of integrated circuits by allowing for efficient stacking of TFTs in the z-direction to provide true three-dimensional (3D) structures for integrated circuits. The techniques described herein are more readily manufacturable than chiplets and similar designs that purport to be 3D.

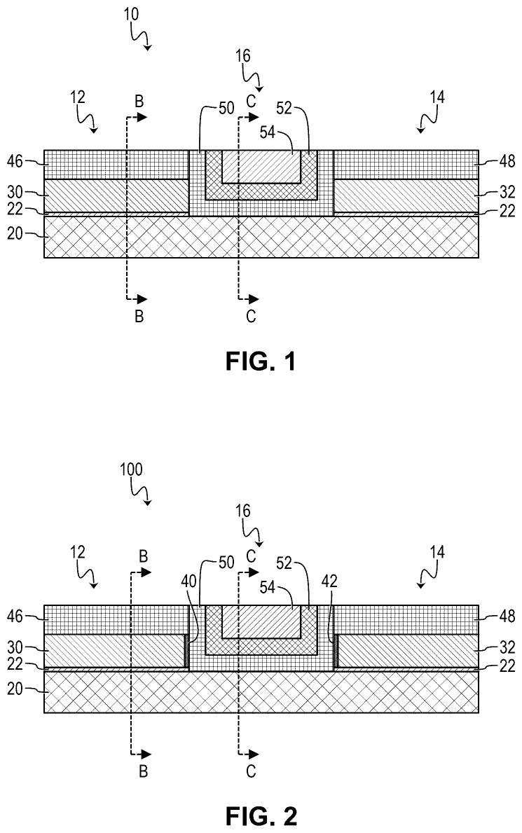

FIG. 1 shows an example TFT 10 according to the present disclosure. The TFT 10 includes a source 12, drain 14, and gate 16. In various examples, the TFT 10 may be manufactured using back end of line (BEOL) and/or middle of line (MOL) processes.

The TFT 10 is formed with a planar substrate 20. The substrate 20 may be disposed over another layer of TFTs, whether manufactured in accordance with the present disclosure or by another technique. For example, the substrate 20 may be disposed over a layer of complementary metal-oxide semiconductor (CMOS) devices or other front end of line (FEOL) devices. In the same example or other examples, layers of TFT 10 may be stacked with suitable intermediate materials/layers, such as interlayer dielectric (ILD), metal layers for electrical connections, etc.

Examples of materials for the substrate 20 include silicon dioxide; silicon nitride; glass; fluorosilicate glass (FSG); a silicon wafer whose surface is processed with wet thermal oxide (WTO) or similar treatment; carbon doped oxide (CDO); organic polymers such as perfluorocyclobutane or polytetrafluoroethylene; organosilicates such as silsesquioxane, siloxane, organosilicate glass; flexible polymer; plastic; etc. Suitable combinations of such materials may also be used.

An adhesion layer 22 may be formed over the substrate 20 to promote adhesion of material to the substrate 20. The adhesion layer 22 may be formed of titanium nitride, hafnium nitride, tin oxide, or similar material. The adhesion layer 22 may be very thin, such as 2 nm or less, 1 nm or less, or 0.5 nm or less.

The source 12 is formed of a body of source material 30 disposed on the substrate 20. In this example, the body of source material 30 is formed by sputtering to a thickness of about 15 nm. In other examples, other source thicknesses may be used, such as about 30 nm, 25 nm, 20 nm, 10 nm, etc.

Examples of source materials include various metals and other conductors, such as nickel, ruthenium, tungsten, cobalt, molybdenum, chromium, copper, titanium nitride, etc. Further examples of source materials include heavily doped n-type materials, degenerate n-type silicon, and III-V compound semiconductors with high conductivity with predominately n-type or electron transport, etc. Suitable combinations of such materials may be used. In this example, the source material is ruthenium.

In this example, the drain 14 is formed of a body of drain material 32 and has the same or similar material and/or structure as the source 12. Accordingly, such material and/or structure may be referred to as “source/drain” or similar terminology. In other examples, the drain 14 has a material and/or structure different to the source 12.

The adhesion layer 22 promotes the adhesion of the bodies of source and drain material 30, 32 to the substrate 20. In other examples, the adhesion layer 22 may be omitted if the source/drain material has suitable adhesion without it.

The source 12 may include a source carrier reservoir 46 that is formed of reservoir material, which is an oxide semiconductor and preferably a metal-oxide semiconductor, such as tin oxide, zinc oxide, etc. The source carrier reservoir 46 may have a naturally high concentration of n-type carriers. The source carrier reservoir 46 may be doped to further increase its n-type concentration. Other examples of materials that may be used for the source carrier reservoir 46 include titanium nitride, indium gallium zinc oxide (IGZO), tungsten oxide, and indium tin oxide (ITO).

The source carrier reservoir 46 may be formed over (with respect to the depicted orientation) and in contact with the body of source material 30. The source carrier reservoir 46 may be formed to a thickness of from about 5 nm to about 20 nm or from about 10 nm to about 15 nm. More specifically, in various examples, the thickness of the source carrier reservoir 46 is about 12.5 nm.

The drain 14 may include a drain reservoir 48. The drain reservoir 48 may have the same or similar structure and/or material as the source carrier reservoir 46. In this example, the drain reservoir 48 is formed of the same reservoir material disposed over and in contact with the body of drain material 32.

If the reservoirs 46, 48 are omitted, then the body of source material 30 and the body of drain material 32 occupy the respective spaces where the reservoirs 46, 48 are depicted.

The TFT 10 further includes a body of semiconductor channel material 50 disposed between the source 12 and drain 14. In this example, the body of channel material 50 is disposed over the source and drain reservoirs 46, 48 (or over the bodies of source and drain material 30, 32, if the reservoirs 46, 48 are not used) and over the substrate 20 between the source 12 and drain 14. The body of channel material 50 is a metal oxide and may be n-type. In this example, the body of channel material 50 is a layer of tin oxide, which is primarily or entirely tin (IV) oxide (SnO₂), with a thickness of about 5 nm to about 10 nm. In this example, the layer of tin oxide is about 7 nm thick.

The tin oxide forming the body of channel material 50 is generally polycrystalline or, more specifically, nanocrystalline. The tin oxide may have a preferred crystallite orientation of Miller index <110> with respect to powder, as determined using grazing-incidence x-ray diffraction (GI-XRD) with ω=0.5° on 20 nm and/or 40 nm thick samples. Nanocrystalline tin oxide with this preferred crystal orientation provides good carrier mobility and good stability, which improves the performance and useful life of the TFT 10.

For sake of clarity, tin oxide with an orientation of <110> means that one of the directions in the family of directions <110>, such as direction [110], is substantially normal to the plane of the substrate 20. In other words, a plane of the family {110}, such as the plane (110), is substantially parallel to the plane of the substrate 20.

The crystallinity of the thin film of tin oxide is preferably at least about 70%. Regions outside the 2θ angular range of 20-60° may be ignored when computing crystallinity.

In various examples, the thin film of tin oxide has a mobility of greater than or equal to 100 cm²/V·s and a carrier concentration of less than or equal to 1.0×10¹⁹ cm⁻³, where these values are measured on the film itself as opposed to the completed TFT 10.

Source carrier reservoir 46 acts as a carrier source adjacent source material 30 and channel material 50 to provide a reservoir of negative charge carriers to mitigate carrier starvation. If used, drain reservoir 48 may serve a similar purpose for the drain 14.

The TFT 10 further includes a body of dielectric material 52 disposed over the body of channel material 50. In this example, the body of gate dielectric material 52 is a layer of generally polycrystalline hafnium oxide that is primarily or entirely hafnium (IV) oxide (HfO₂) with a preferred crystallite orientation of Miller index <−111> (also written as <1̅11>) with respect to powder, as determined using grazing-incidence x-ray diffraction (GI-XRD) with ω=0.5° on 20 nm and/or 40 nm thick samples. Polycrystalline hafnium oxide with this preferred crystal orientation provides good stability, which improves the performance and useful life of the TFT 10. While other crystallite orientations, such as <020>, <100>, <200>, and <111>, may be present, it is preferred that the body of dielectric material 52 has a dominant crystallite orientation of <−111>. The crystallinity of the thin film of hafnium oxide is preferably at least about 80%, more preferably at least about 85%, more preferably at least about 90%, and still more preferably at least about 95%. In other examples, the body of gate dielectric material 52 is amorphous. The body of gate dielectric material 52 has a suitable thickness, such as about 10-15 nm thick, or more particularly, about 12.5 nm.

The TFT 10 further includes a body of gate material 54 (also termed “gate metal”) disposed over the gate dielectric material 52. The gate material is a conductor. Examples of gate materials include tungsten, titanium, titanium nitride, molybdenum, gold, platinum, aluminum, nickel, copper, chromium, hafnium, indium, manganese, iron, vanadium, zinc, tantalum, or alloys/combinations thereof. In this example, the body of gate material 54 is a layer of tungsten.

In operation, when a voltage is applied across the source 12 and drain 14, and when a suitable voltage is applied to the gate 16, a carrier channel forms in the body of semiconductor channel material 50, which causes flow of current between source 12 and drain 14.

FIG. 2 shows another example TFT 100 according to the present disclosure. The TFT 100 is substantially the same as the TFT 10 except that source and drain channel interfaces 40, 42 are provided. The above description may be referenced for details not repeated below.

The TFT 100 includes a body of source material 30 that may be subject to inline treatment, such as plasma treatment, anneal treatment, chemical or electro-chemical treatment, or similar. Different types of treatment may be combined. A treatment may be repeated two or more times.

The treatment may form a p-type source-channel interface 40 at the body of source material 30 at least between the body of source material 30 and semiconductor channel material 50. The source-channel interface 40 may tune the threshold voltage at which the TFT 100 turns on to reduce leakage current through TFT 100 in the off state. The source-channel interface 40 may create a repository of complimentary excess positive or negative charge that functions to deplete the channel in at least the region of the body of channel material 50 adjacent to the body of source material 30. In this manner, the source-channel interface 40 serves as a voltage-controlled electron transport barrier, resulting in substantially less current flow through body of channel material 50 when the TFT 100 is in an off state. Further, the source-channel interface 40 may also serve to reduce stress induced leakage currents (“SILC”) in TFT 100 by inhibiting the formation of interlayer stress-induced flaws between the body of channel material 50 and the body of source material 30. A drain-channel interface 42 may be similarly formed and may have similar characteristics, but it is contemplated that the source-channel interface 40 provides significant benefit without the drain-channel interface 42 and may provide most or all of the benefit.

In this example, the bodies of source and drain material 30, 32 are separate and not contiguous.

In this example, the bodies of source and drain material 30, 32 are treated with oxygen plasma to form a layer of oxidized material that are the source and drain channel interfaces 40, 42. In the example of ruthenium as source/drain material, the source and drain channel interfaces 40, 42 are consequently formed of ruthenium oxide, which is contemplated to be primarily or exclusively of the +4 oxidation state, i.e., RuO₂.

Nitrogen plasma may be used in conjunction with this oxygen plasma treatment with the result being that one or both of the source-channel interface 40 and drain-channel interface 42 may be doped with less than about 20% nitrogen, such as about 12-14% nitrogen or, in further examples, about 6-7% nitrogen or, in still further examples, about 3-4% nitrogen. In other examples, chlorine and/or fluorine may be used.

In various examples, any one or suitable combination of nitrogen, chlorine, and/or fluorine may be used. Nitrogen, chlorine, or fluorine may increase the stability of the ruthenium oxide.

In one such example, nitrogen and chlorine are used in approximately equal amounts. For instance, the ruthenium oxide may be somewhat oxygen deficient, as expressed by RuO_{2-Δ}, and approximately 0.5Δ nitrogen and 0.5Δ chlorine are introduced to the ruthenium oxide for sake of stability.

In other examples, the bodies of source and drain material 30, 32 may be formed using atomic-layer deposition or other deposition process.

For further detail concerning the source and drain channel interfaces 40, 42 and other aspects of the TFTs described herein, reference may be made to U.S. Pat. No. 11,949,019, which is incorporated herein by reference.

In operation, when a voltage is applied across the source 12 and drain 14, and when a suitable voltage is applied to the gate 16, a carrier channel forms in the body of semiconductor channel material 50, which causes flow of current between source 12 and drain 14. When the voltage is removed, the flow of current is reduced to a very low amount, assisted by the source-channel interface 40 and, optionally, the drain-channel interface 42. An on-to-off current ratio of about 10¹⁰ has been measured in various tests.

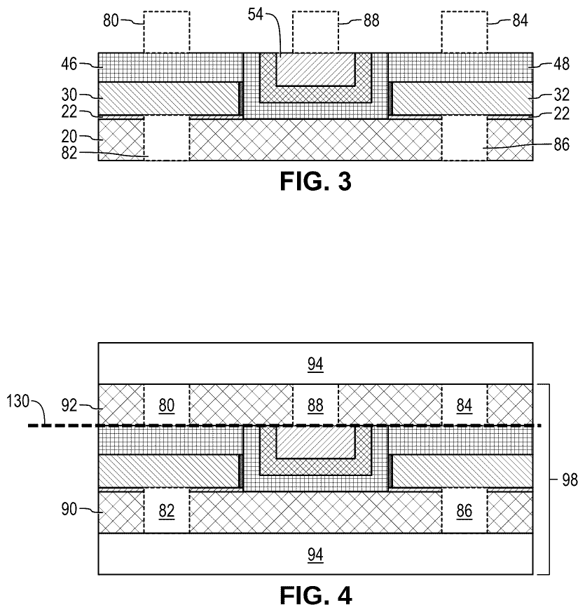

FIG. 3 shows example electrode connections to the TFT 100 of FIG. 2. Such connections also apply to the TFT 10 of FIG. 1. Example electrodes include a body/layer of metal or other conductor formed as a trace, via, or similar structure. Example materials for electrodes include tungsten, titanium, copper, aluminum, and other materials discussed above for the body of gate material 54.

A source electrode 80 may be provided in contact with the source carrier reservoir 46 from above (all mention of directions/orientations are with respect to the orientation depicted and are non-limiting). Alternatively, a source electrode (e.g., a via) 82 may penetrate the substrate 20 (which may be ILD), and optionally the adhesion layer 22, to contact the body of source material 30 from below.

Similarly, a drain electrode 84 may be provided in contact with the drain carrier reservoir 48 from above. Alternatively, a drain electrode 86 may penetrate the substrate 20, and optionally the adhesion layer 22, to contact the body of drain material 32 from below.

Source and drain electrode positions are independent. Each may be positioned above or below, irrespective of the position of the other.

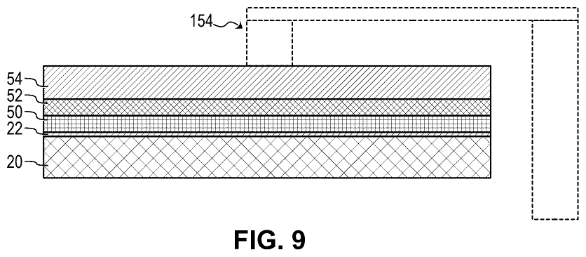

A gate electrode 88 may be provided in contact with the body of gate material 54 from above. Alternatively, as shown in FIG. 9, a gate electrode 154 may extend laterally (perpendicular to the page of FIG. 3) and downwards for connection below the TFT 10, 100, 200. Such gate electrode 154 may be made from any suitable combination of vias, metallization, traces, etc.

The material of an electrode 80, 82, 84, 86, 88 may be any suitable conductor, such as those given above for the body of source material 30 and the body of gate material 54.

As shown in FIG. 4, select electrodes (e.g., vias) 80, 82, 84, 86, 88 may be formed within layers of ILD 90, 92 (or other substrate), which may be positioned above and/or below the TFT 10, 100, 200 to electrically isolate the TFT 10, 100, 200 from adjacent layers. One or more wiring layers 94 (metallization layers) may be positioned adjacent ILD 90, 92 to provide electrical connections to those of the electrodes 80, 82, 84, 86, 88 selected for use in given implementation. A stack unit 98 of TFTs 10, 100, 200 with an interconnect wiring layer 94 may thus be defined. A stack unit 98 may be stacked, any suitable number of times, to provide various 3D circuit layouts. The wire layer 94 of a unit stack 98 includes electrical connections among TFTs 10, 100, 200 and/or other devices provided to the same stack unit 98 or to different stack units 98.

As will be discussed in detail below, the TFT 10, 100, 200 is planarized to a planar surface 130 to facilitate stacking.

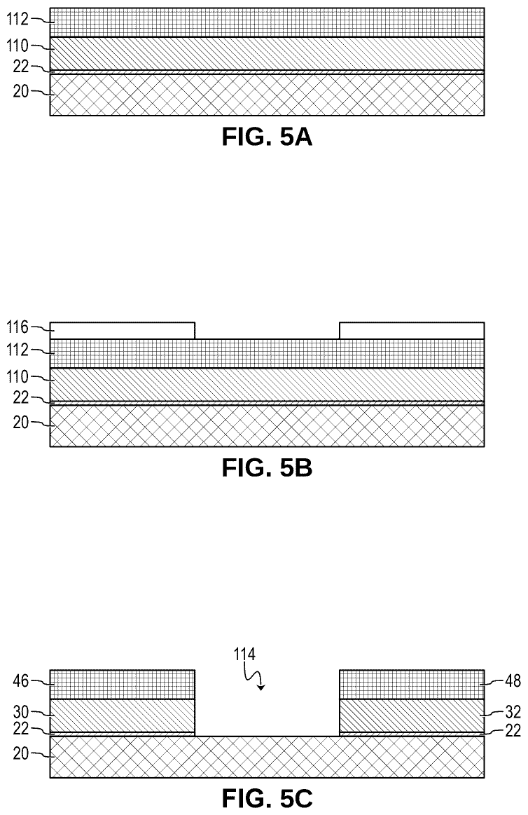

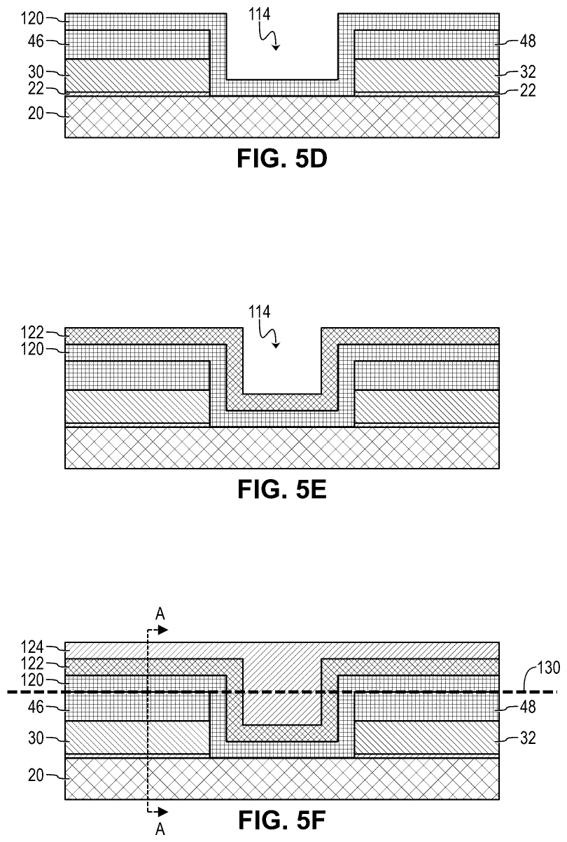

With reference to FIGS. 5A-5F, a TFT 10, 100, 200, as described herein, may be manufactured using FEOL processes, MOL processes, BEOL processes, or a combination of such. A manufacturing process may include forming one or more stacks of TFTs over other stacks of TFTs and/or other devices made using FEOL, MOL, and/or BEOL processes.

The manufacture of materials, layers, and/or features of semiconductor devices is referred to herein as “forming.” As will be apparent to those of ordinary skill in the art, unless otherwise mentioned, “forming” is intended to include all semiconductor manufacturing techniques suitable and applicable therefor including, without limitation, deposition (e.g., chemical vapor deposition or CVD, atomic layer deposition or ALD, physical vapor deposition or PVD, etc.), plasma-enhanced/assisted atomic layer deposition (PEALD/PAALD), thermal ALD (T-ALD), plasma-enhanced chemical vapor deposition (PECVD), sputtering, lithography/photolithography, etching, implantation, annealing, oxidation, and similar processes. While examples of specific types of forming are given below, it should be understood that comparable methods of forming may be alternatively or additionally used, unless otherwise mentioned, without departing from the present disclosure.

During manufacture, the TFT in its partially or fully complete state may be subject to an anneal, such as a forming gas (i.e., nitrogen and hydrogen) anneal, as may be required for various reasons, such as to stabilize material or to support the forming of material of the TFT or other materials, components, or devices that are formed before or after the TFT is formed. Any suitable number and configuration of forming gas anneals may be performed. Annealing may be done at about 400° C. for about 120 minutes, for example, or longer (e.g., 3 or 4 hours). Higher temperatures and longer times may also be useful.

With reference to FIG. 5A, a substrate 20 may be formed as discussed above. The substrate 20 may be ILD. An adhesion layer 22 of, for example, titanium nitride may be formed over the substrate by ALD, for example.

A layer of source/drain material 110, e.g., ruthenium, is formed over the adhesion layer 22. The layer of source/drain material 110 may be formed by sputtering to a desired thickness.

If the carrier reservoirs 46, 48 are used, a layer of reservoir material 112, e.g., tin oxide, is formed over the layer of source/drain material 110. The layer of reservoir material 112 may be formed by ALD, for example, to a desired thickness.

With reference to FIGS. 5B and 5C, the layer of source/drain material 110 is patterned to form separate bodies of source and drain material 30, 32 with a gap 114 therebetween. If the layer of reservoir material 112 is used, it may be patterned at the same time with the same process to form the carrier reservoirs 46, 48. Lithography and etching, such as inductively coupled plasma reactive ion etching (ICP-RIE), may be used. A pattern of photoresist 116 may be formed on the layer of reservoir material 110 (or layer of source/drain material 112) to establish the etching pattern. The adhesion layer 22, if used, should also be etched to avoid shorting the source 12 and drain 14.

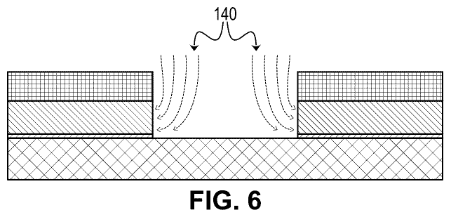

If the source and drain channel interfaces 40, 42 are used, they may be formed at this time as discussed below with respect to FIG. 6.

Subsequently, with reference to FIG. 5D, a layer of channel material 120 is formed over the carrier reservoirs 46, 48 and between the bodies of source and drain material 30, 32 and over the substrate 20 within the gap 114.

The layer of channel material 120, i.e., tin oxide, may be formed by PEALD with oxygen plasma, T-ALD, or similar technique. Tetraallyltin may be used as the precursor. In various examples, chlorine, fluorine, nitrogen, or other chemical species may be introduced during the deposition process, so that the layer of channel material 120 includes such species.

Annealing may be useful to develop and/or maintain the preferred crystallite orientation of the tin oxide discussed above. Annealing may be performed immediately after deposition of the layer of channel material 120 or at a later stage. Example anneal conditions when using PEALD to deposit the layer of channel material 120 are 400° C. for about 120 minutes under forming gas. Example anneal conditions for when using T-ALD to deposit the layer of channel material 120 are 400° C. for about 60 to about 120 minutes under vacuum.

As shown in FIG. 5E, after the layer of channel material 120 is formed, a layer of gate dielectric material 122, e.g., hafnium oxide, is formed over the layer of channel material 120. The layer of gate dielectric material 122 may be formed by ALD to a desired thickness. Annealing may be useful to develop and/or maintain the preferred crystallite orientation of hafnium oxide, discussed above. Annealing may be performed immediately after deposition of the layer of gate dielectric material 122 or at a later stage. Example anneal conditions are 400° C. for 120 minutes.

Subsequently, as shown in FIG. 5F, a layer of gate material 124 is formed over the layer of gate dielectric material 122. This includes filling the remainder of the gap 114 with gate material, which will ultimately form the body of gate material 54. The layer of gate material 124 may be formed by sputtering.

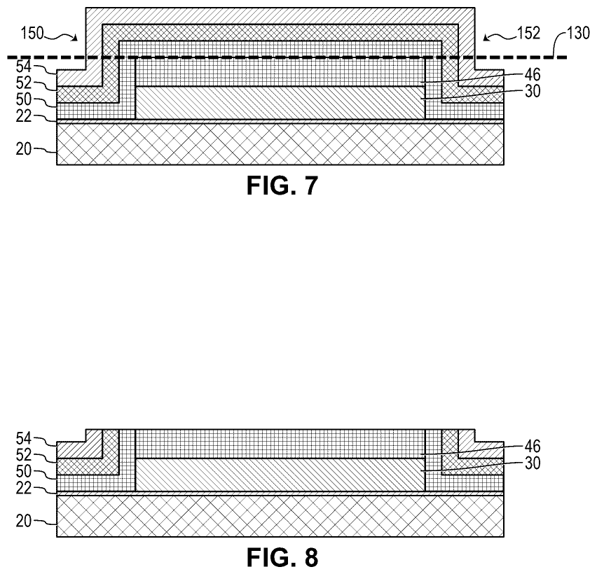

As shown in FIGS. 7 and 8, which show, respectively, the TFT 10, 100 from the left with respect to FIG. 5F (FIG. 7 before etching and polishing; FIG. 8 after), the layer of channel material 120, layer of gate dielectric material 122, and layer of gate material 124 wrap around the underlying structure, as indicated at 150, 152, to encapsulate the body of source material 30 and the body of drain material 32 (not shown) and the source carrier reservoir 46 and drain reservoir 48, if used.

Next, referring back to FIG. 5F, the structure is planarized to a planar surface (or plane) 130 that is parallel to the substrate 20. The plane 130 extends through the reservoirs 46, 48 or the bodies of source and drain material 30, 32, if the reservoirs 46, 48 are not used. The plane 130 may be positioned to remove as little or as much of the reservoir material (or source/drain material) as desired. Planarization may be performed by etching to a suitable etch stop followed by chemical mechanical polishing (CMP).

Planarization also removes portions of the layer of channel material 120, layer of gate dielectric material 122, and layer of gate material 124 that overlie the bodies of source/drain material 30, 32. As such, the transistor 10, 100, 200 can be said to have a self-aligned structure, in that the gate does not overlie the source or drain. In addition, the lateral distance between the gate and source/drain is controlled by the deposited thicknesses of the channel and dielectric materials 50, 52, meaning that the lateral distance is predictably precise.

Planarization also removes any excess material (not shown), such as substrate material (e.g., ILD), that is present around the TFT 10, 100, 200 (to the left and right of the TFT depicted) and above the surface 130. That is, the TFT 10, 100, 200 may be formed in recesses within ILD (or other substrate material) or ILD may be formed around the TFT 10, 100, 200, for example, and such ILD and any other excess material may be planarized at the same time that the TFT 10, 100, 200 is planarized.

As such, the reservoirs 46, 48 or the bodies of source and drain material 30, 32, if the reservoirs 46, 48 are not used; the layer of channel material 120; the layer of gate dielectric material 122; and the layer of gate material 124 all terminate at the common planar surface 130. In other words, the reservoirs 46, 48 (the bodies of source and drain material 30, 32), the layer of channel material 120, the layer of gate dielectric material 122, and the layer of gate material 124 are all flush with the surface 130. Accordingly, a layer of ILD or other substrate material may be formed over the planar surface 130 to facilitate wiring (vias and/or lateral wires) and another layer of TFTs 10, 100, 200 over such wiring.

After planarization, a transistor 10, 100, 200 with a structure, as shown and described herein, is formed.

Further forming may be performed, such as annealing, as may be required for the particular application of the TFT 10, 100, 200.

FIG. 6 shows an example of process of forming source and drain channel interfaces 40, 42. This includes treating the bodies of source and drain material 30, 32 with plasma 140, or similar treatment, to form a layer of oxidized material. In various examples, a sequence of plasma treatments is used as follows: argon (˜95%) and hydrogen (˜5%) plasma at 190° C. for a duration of about 10 seconds; then oxygen plasma at 190° C. for a duration of about 60 seconds; and then nitrogen plasma at 190° C. for a duration of about 30 seconds. Remote plasma processing may be used with carrier gas, such as argon. This sequence may be repeated two or more times. As discussed above, when ruthenium is used as the source/drain material, the resulting source and drain channel interfaces 40, 42 include ruthenium oxide that is doped with nitrogen. If less or no nitrogen is desired, the 30 seconds of nitrogen plasma may be shortened or omitted. See above for example doping concentrations.

In other examples, a sequence of plasma treatments is used as follows: argon (˜95%) and hydrogen (˜5%) plasma at 190° C. for a duration of about 10 seconds; then oxygen plasma at 190° C. for a duration of about 60 seconds; and then chlorine plasma at 20° C. for a duration of about 30 seconds. Remote plasma processing may be used with carrier gas, such as argon. This sequence may be repeated two or more times. As discussed above, when ruthenium is used as the source/drain material, the resulting source and drain channel interfaces 40, 42 include ruthenium oxide that is doped with chlorine.

In other examples, a sequence of plasma treatments is used as follows: argon (˜95%) and hydrogen (˜5%) plasma at 190° C. for a duration of about 10 seconds; then oxygen plasma at 190° C. for a duration of about 60 seconds; and then fluorine plasma at 20° C. for a duration of about 30 seconds. Remote plasma processing may be used with carrier gas, such as argon. This sequence may be repeated two or more times. As discussed above, when ruthenium is used as the source/drain material, the resulting source and drain channel interfaces 40, 42 include ruthenium oxide that is doped with fluorine.

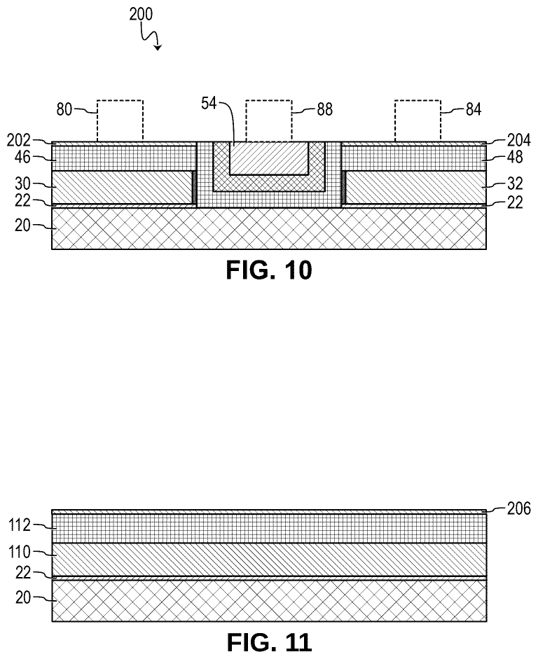

FIG. 10 shows another example TFT 200 according to the present disclosure. The TFT 200 is similar to the TFT 100 and only differences will be discussed in detail.

The TFT 200 includes an intermediate contact layer 202 formed over the source carrier reservoir 46 and another intermediate contact layer 204 formed over the drain reservoir 48. Each contact layer 202, 204 is provided to create a suitable ohmic contact with the respective reservoir 46, 48 and the respective electrode 80, 84.

In various examples, when tin oxide is used as the reservoir material, a contact layer 202, 204 may be composed of silicon doped tin. The amount of silicon may be selected to raise the melting point of the material to about 400° C. or more, which is compatible with BEOL processes. For example, silicon may be provided at a proportion of 5% or less, 2% or less, or 1% or less.

With reference to FIG. 11, during manufacture, a layer of intermediate contact material 206 may be formed over a layer of reservoir material 112 after the state shown in FIG. 5A. Deposition may be simplified when the layer of reservoir material 112 and the layer of intermediate contact material 206 both include tin. The layer of intermediate contact material 206 may then be patterned with the same process described for FIGS. 5B-5C to form the contact layers 202, 204. The intermediate contact material, as present in the contact layers 202, 204, may be referenced to define the limit of planarization (FIG. 5F). For example, the intermediate contact material may be used as an etch stop or as a reference to halt CMP.

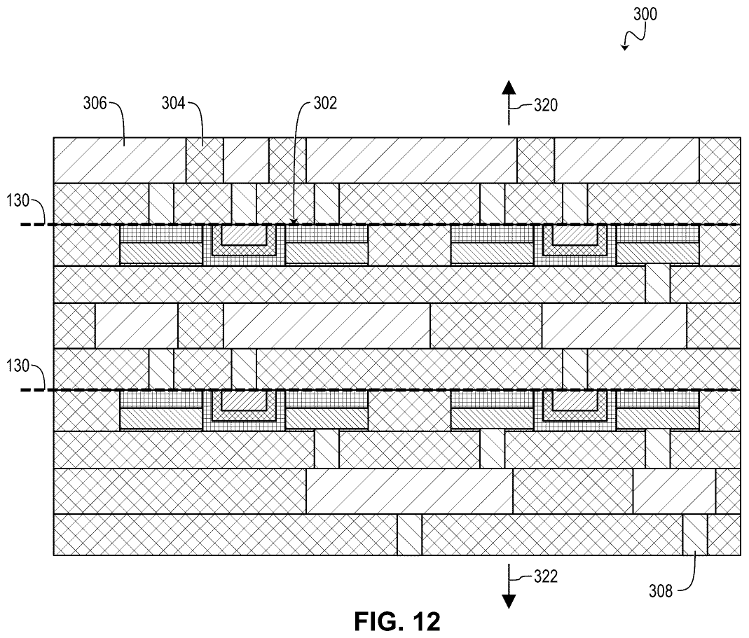

With reference to FIG. 12, which expands on the discussion above for FIGS. 3 and 4, an example stacked arrangement 300 of TFTs 302, such as TFT 10, 100, 200 or any other TFT described herein, is shown.

TFTs 302 are formed on layers of substrate 304, such as ILD or other substrate discussed herein. Interconnect wiring, such as lateral interconnect wires 306 (e.g., metal traces) and vertical vias 308 are formed on or in, as the case may be, the layers of substrate 304 to electrically interconnect sources, drains, and/or gates of the TFTs 302 to form an integrated circuit.

The stacked arrangement 300 is depicted with two layers of TFTs 302. It should be understood that any practical number of layers may be formed, extending in the upwards direction 320 and/or downwards direction 322. The stacked arrangement 300 may be formed over a bottom layer of conventional transistors, such as CMOS devices.

Planarization to a planar surface 130 may be performed, such that excess material of a layer of TFTs 302 and excess substrate 304 material around the TFTs 302 are planarized simultaneously.

In view of the above, it should be apparent that TFTs according to this disclosure are stackable and self-aligned. This may help increase density of integrated circuits by allowing for efficient stacking of TFTs, as opposed to being limited to lateral layouts. The self-aligned characteristic reduces or eliminates undesirable capacitance between gate and/source drain.

Auxiliary verbs “can” and “may” are used interchangeably herein to denote components, features, and/or aspects of the present disclosure that are capable, configurable, selectable, modifiable, or optional, as would be apparent to one of ordinary skill in the art given the benefit of this disclosure. These terms should not be taken as limiting the present disclosure, unless otherwise specified.

Spatial prepositions, such as “over”, “under”, “above”, “below”, “up”, “down”, “beside”, etc., are provided for sake of explanation and should not be taken as limiting the present disclosure to an absolute spatial orientation or arrangement, unless otherwise specified. For example, one of ordinary skill in the art would understand that a first element is above or below a second element depending on the perspective of the observer.

The articles “a”, “an”, “the”, “said”, etc. indicate singular and plural, unless otherwise specified.

The conjunction “or” is used inclusively and should be understood to mean “and/or”, unless otherwise specified.

Sets of elements A, B, C described as A, B, or C; A, B, and C; A, B, and/or C; or A, B, C should be considered open sets from which one or more elements or a combination of one or more elements may be selected, unless otherwise specified. Sets of elements are open, unless specified to be closed, for example, by use of the term “consist”, “consisting”, or similar closed language.

The above clarifications apply to both the specification and claims.

The figures are not to scale, unless otherwise specified.

The above-described embodiments of the invention are intended to be examples of the present disclosure and alterations and modifications may be effected thereto, by those of ordinary skill in the art, without departing from the scope of the invention which is defined solely by the claims appended hereto.

1. A method of making a thin-film transistor, the method comprising:
forming a structure of layers between and over a source and a drain, the structure of layers including a layer of metal-oxide semiconductor channel material, a layer of dielectric material, and a layer of gate material; and
planarizing the structure to remove portions of the layers that overlie the source and the drain.

2. The method of claim 1, wherein the planarizing includes planarizing the structure to a source carrier reservoir of the source that overlies a body of source material of the source.

3. The method of claim 1, wherein the planarizing includes etching.

4. The method of claim 1, wherein the planarizing includes chemical mechanical polishing.

5. The method of claim 1, further comprising:
forming an adhesion layer of tin oxide on a substrate; and
forming bodies of source and drain material on the adhesion layer;
wherein the adhesion layer promotes adhesion of the bodies of source and drain material to the substrate.

6. The method of claim 5, wherein the substrate is an interlayer dielectric.

7. The method of claim 1, further comprising forming a source-channel interface at a body of source material of the source, the source-channel interface contacting the metal-oxide semiconductor channel material and being operable to deplete a region of the metal-oxide semiconductor channel material when the thin-film transistor is off.

8. The method of claim 7, further comprising doping the source-channel interface with nitrogen, chlorine, fluorine, or a combination of two or more of such.

9. The method of claim 7, further comprising forming a drain-channel interface at a body of drain material of the drain, the drain-channel interface being formed in the same manner as the source-channel interface.

10. The method of claim 1, further comprising forming a layer of intermediate contact material over the source and drain to provide ohmic contact to an electrode.

11. The method of claim 10, wherein the intermediate contact material defines a limit of the planarizing.

12. The method of claim 1, further comprising:
forming a substrate over a planar surface formed by the planarizing; and
forming another thin-film transistor over the substrate, including forming and planarizing another structure of layers.

13. The method of claim 12, wherein the substrate is an interlayer dielectric.

14. A thin-film transistor comprising:
a source including a body of source material;
a drain spaced apart from the source, the drain including a body of drain material; and
a structure of layers between the source and the drain, the structure of layers including a layer of metal-oxide semiconductor channel material, a layer of dielectric material, and a layer of gate material;
wherein the source, the drain, and the structure of layers terminate at a common planar surface.

15. The thin-film transistor of claim 14, wherein the source further comprises a source carrier reservoir that overlies the body of source material.

16. The thin-film transistor of claim 14, further comprising:
a substrate; and
an adhesion layer of tin oxide formed on the substrate; and
wherein the bodies of source and drain material are formed on the adhesion layer;
wherein the adhesion layer promotes adhesion of the bodies of source and drain material to the substrate.

17. The thin-film transistor of claim 16, wherein the substrate is an interlayer dielectric.

18. The thin-film transistor of claim 14, further comprising an intermediate contact layer at the source to provide ohmic contact to an electrode, wherein the intermediate contact layer is formed of silicon doped tin.

19. A stacked arrangement of thin-film transistors, comprising:
a stack formed of stack units, each stack unit including a plurality of thin-film transistors, each thin-film transistor of the plurality of thin-film transistors including:
a source;
a drain spaced apart from the source; and
a structure of layers between the source and the drain, the structure of layers including a layer of metal-oxide semiconductor channel material, a layer of dielectric material, and a layer of gate material;
wherein the source, the drain, and the structure of layers terminate at a common planar surface.

20. The stacked arrangement of thin-film transistors of claim 19, wherein each stack unit further comprises:
interlayer dielectric on which the source and drain of respective thin-film transistors are formed; and
interconnect wiring to electrically connect selected ones of the thin-film transistors within a respective stack unit, between different stack units, or both within the respective stack unit and between the different stack units.
